(19) United States
(12) Patent Application Publication
(10) Pub. No.: US 2026/0162752 A1
(43) Pub. Date: Jun. 11, 2026

(54) APPARATUSES, SYSTEMS, AND METHODS FOR MAPPING REPAIR ADDRESSES FOR A MEMORY DEVICE

(71) Applicant: Micron Technology, Inc., Boise, ID (US)

(72) Inventors: Sujeet Ayyapureddi, Boise, ID (US); Gary Howe, Allen, TX (US)

(73) Assignee: Micron Technology, Inc., Boise, ID (US)

(21) Appl. No.: 18/975,772

(22) Filed: Dec. 10, 2024

(51) Int. Cl. G11C 29/00; G11C 29/46

(52) U.S. Cl. CPC G11C 29/76; G11C 29/46; G11C 29/787

(57) ABSTRACT

A memory device may include a memory array organized into banks, which are organized into column planes with multiple column selects signals. The addresses for column select signals within a plane may be remapped to different column select signals within the plane by setting one or more swap bits. In some examples, two swap bits may be provided. In some examples, the swap bits may permit swapping of the two most significant bits of the column select address. One or both of the swap bits may be set. For example, the most significant bit, the next most significant bit, or both may be flipped.

### BACKGROUND

This disclosure relates generally to semiconductor devices, and more specifically to semiconductor memory devices. In particular, the disclosure relates to memory, such as dynamic random access memory (DRAM). Information may be stored in memory cells, which may be organized into rows (word lines) and columns (bit lines) of an array. Various types of information may be stored in the array, such as data, error correction code (ECC) data, and metadata. The data may be information provided by an external device (e.g., controller, processor, host system). The ECC data may provide information that may be used to detect and/or correct errors in the data. The metadata may provide information about the data, ECC data, the memory device, and/or a device in communication with the memory device (e.g., a controller).

DRAM users are increasingly using metadata to supplement the data stored in the memory array. However, not all DRAM users utilize metadata, and DRAM users may vary on how much of the memory array they want to dedicate to memory devices. Accordingly, memory devices may accommodate metadata storage modes and non-metadata storage modes, for example, as described in U.S. Provisional Patent Application Nos. 63/695,446, 63/695,458, 63/695,465, 63/695,472, 63/695,482, and 63/695,495 filed Sep. 17, 2024, which are incorporated herein by reference for any purpose. Further, some memory devices may accommodate multiple metadata storage modes in addition to a non-metadata storage mode as described in U.S. patent application Ser. Nos. 18/916,497 and 18/916,521 filed Oct. 15, 2024, which are incorporated herein by reference for any purpose.

At various points in manufacturing and use of a memory device, one or more memory cells may fail (e.g., become unable to store information, be inaccessible by the memory device, etc.) and may need to be repaired. The memory device may perform repair operations on a row-by-row basis and/or column-by-column basis. For example, during a column repair operation, a column containing a failed memory cell (which may be referred to as a defective column or a bad column) may be identified. The memory device may contain an additional column of memory (which may also be referred to as redundant column) which may be used in repair operations. During a repair operation, a column address associated with the defective column may be redirected (e.g., remapped), such that the column address points to a redundant column instead.

For example during a repair operation for a defective column select, a column address associated with the defective column select may be redirected so that it is associated with one of the redundant column selects in a global column redundancy plane instead. In some modes of operation, the repair operation may be a hard (or permanent) repair operation, where updated memory line address information is stored in the memory in a non-volatile form (e.g., stored in a manner that is maintained even when the memory device is powered down). For example, the memory device may include a fuse array, which may include fuses (and/or anti-fuses), each of which may have a state that can be permanently changed (e.g., when the fuse/anti-fuse is “blown”). The state of the fuses/anti-fuses in the fuse array may, in part, determine which addresses are associated with which lines of memory. In some applications, the fuse array is provided at the bank level (e.g., fuse banks). In other applications, the fuse array is provided external to the memory banks, and repair information is “broadcast” to the banks during a broadcast operation. The memory banks may include latches, registers, and/or other logic for storing and utilizing the repair operation to remap defective memory lines to redundant lines in the banks.

### BRIEF DESCRIPTION OF THE DRAWINGS

FIG. 1 is a block diagram of at least a portion of a computing system according to some embodiments of the present disclosure.

FIG. 2 is a block diagram of a semiconductor device according to some embodiments of the present disclosure.

FIG. 3 is a block diagram of a portion of a memory device according to some embodiments of the present disclosure.

FIG. 4 shows a table indicating organization of a bank of the memory array and physical column plane suppression scheme according to some embodiments of the present disclosure.

FIG. 5 is a flow chart of a method according to embodiments of the present disclosure.

FIG. 6 is a flow chart of a method according to embodiments of the present disclosure.

### DETAILED DESCRIPTION

The following description of certain embodiments is merely exemplary in nature and is in no way intended to limit the scope of the disclosure or its applications or uses. In the following detailed description of embodiments of the present systems and methods, reference is made to the accompanying drawings which form a part hereof, and which are shown by way of illustration specific embodiments in which the described systems and methods may be practiced. These embodiments are described in sufficient detail to enable those skilled in the art to practice presently disclosed systems and methods, and it is to be understood that other embodiments may be utilized and that structural and logical changes may be made without departing from the spirit and scope of the disclosure. Moreover, for the purpose of clarity, detailed descriptions of certain features will not be discussed when they would be apparent to those with skill in the art so as not to obscure the description of embodiments of the disclosure. The following detailed description is therefore not to be taken in a limiting sense, and the scope of the disclosure is defined only by the appended claims.

Semiconductor memory devices may store information in multiple memory cells. The information may be stored as a binary code, and each memory cell may store a single bit of information as either a logical high (e.g., a “1”) or a logical low (e.g., a “0”). The memory cells may be organized at the intersection of word lines (rows) and bit lines (columns) an array. The memory may further be organized into one or more memory banks. The banks may be organized into bank groups, where each bank group includes one or more banks. Each bank may include multiple of rows and columns. During operations, the memory device may receive a command and an address which specifies one or more rows and one or more columns and then execute the command on the memory cells at the intersection of the specified rows and columns (and/or along an entire row/column). The address may further specify the bank group and/or bank for execution of the command. In some applications, rows may be specified by 17-bit row addresses and columns may be specified by 12-bit column addresses. However, the number of bits used for the addresses may vary depending on the size and/or organization of the memory.

The columns may generally be organized into column planes, each of which includes a number of sets of individual columns all activated by a column select signal (CS) (e.g., column selects). Each bank may include some number X column planes. A column plane may receive some number N of column select (CS) signals, each of which may activate some number M of individual bit lines. As used herein, a column select set or CS set may generally refer to a set of bit lines which are activated by a given value of the CS signal within a column plane. The column select signal may be represented by (all or a portion of) a column address (CA). Responsive to a column select signal, data may be provided from corresponding locations from the column planes. The data from the column planes associated with the column select signal may be referred to as a prefetch.

As discussed in the Background section, memory devices may have different operation modes where different amounts of metadata are stored (e.g., different storage modes). For example, a memory device may have two modes: MD ON (metadata is stored) and MD OFF (metadata is not stored). In another example, a memory device may have three modes: MD16 ON (16 bits of metadata per prefetch are stored), MD8 ON (8 bits of metadata per prefetch are stored), and MD OFF (no metadata is stored). The arrangement of the memory array of the memory device may change based on the storage mode. For example, a memory device may include a memory array that is selectively configurable (e.g., enabled) to store different amounts of metadata (e.g., none, 8 bits, and 16 bits per prefetch). The memory array may include 16 column planes for data, two column planes for metadata, and a column plane for ECC data (total=19 CP) in some applications. The storage modes may be enabled by storing a value in a mode register in some applications.

When MD16 ON is enabled, 14 of the data column planes are associated with 56 column select signals, 2 of the data column planes are associated with 60 column select signals, the metadata planes are associated with 60 column select signals, and the ECC data plane is associated with 64 column select signals (total=19 CP per bank). In this storage mode, the physical column planes (e.g., physical planes) of the memory device associated with data and metadata are accessed by activating the corresponding column select signals for the physical column planes.

When MD8 ON is enabled, the column select signals may be activated in a manner such that the memory array operates as if there are sixteen data planes, one metadata plane, and an ECC data plane (total=18 CP per bank). When MD OFF is enabled, the column select signals may be activated in a manner such that the memory array operates as if there are sixteen data planes and an ECC data plane (total=17 CP per bank). IN MD8 ON and MD OFF, the memory device may configure the column select signals to be activated in a manner to form a number of virtual column planes (e.g., virtual planes) to access metadata and/or data. The number of virtual planes may be less than the number of data and metadata physical planes (e.g., 16 data+2 metadata=18 total physical planes vs. 17 or 16 total virtual planes). The number of bit lines activated on the virtual planes may be equal to the number of bits lines activated in the physical planes during a memory access operation. By “virtual planes” it is meant that column select signals may be activated or suppressed in a manner that does not correspond to the physical planes of the memory array of the memory device. However, from the viewpoint of an external device such as a controller, the memory device may receive and output data and/or metadata as if the virtual planes were physical column planes.

Certain memory cells may be defective, and memory lines (e.g., rows or columns) containing one or more defective memory cells may generally be referred to as defective lines or bad lines (e.g., defective/bad rows or columns). The defective lines may be incapable of storing information and/or may become otherwise inaccessible to the memory device. The memory device may carry out one or more types of repair operations to resolve the defective lines. Memory banks may generally include a number of additional memory lines, which may generally be referred to as redundant lines (e.g., redundant rows and/or redundant columns). A bank of the memory array of a memory device may include a global column redundancy (GCR) plane. The redundant column selects in the GCR plane may be available to repair bad column selects in any of the other column planes of the bank. In some cases, this plane may include fewer column selects than the “regular” column planes (e.g., 16 instead of 56-64). The control logic for the GCR plane may receive the column address of the repaired column select as well as the column plane where the repaired column select is located. The information may be used to remap (e.g., by muxing or other means) the original column select in the column plane to a column plane in the GCR plane. Thus, when a memory access operation attempts to access an address associated with a defective column select in a column plane, a redundant column select in the GCR plane is accessed instead.

In some memory devices, the GCR plane can only repair one column select address for one column plane. For example, the GCR plane may repair CS16 in CP09 and CS20 in CP10 without issue. However, if CS16 is defective in both CP09 and CP10, the GCR plane may not be capable of repairing both because the CS16 of both CP09 and CP10 would be remapped to the same redundant column select in the GCR plane. To resolve this issue, the memory device may include swap bits associated with one or more planes of one or more banks of the memory array. A swap bit may allow the most significant bit of a column address to be flipped (e.g., “0”->“1” and “1”->“0”) to remap the column select signal to another column address. The swap bits may be stored in fuse registers, which are written to from a central fuse array during a broadcast operation, or in fuse banks associated with the memory banks.

Turning back to the above example, when CS16 is defective in CP09 and CP10, the swap bit is set for CP09 and/or CP10. Setting the swap bit remaps CS16 to CS48 and/or CS48 to CS16 (e.g., swapping them). Now, the GCR plane can be used to repair CS16 of one of the column planes and replace CS48 in the other column plane. Continuing the example, a swap bit of CP09 may be used to remap CS16 to CS48. Effectively, CS48 is used to “repair” CS16. Now, the defective column selects are CS16 in CP10 and CS48 in CP09, rather than CS16 being defective in both CP09 and CP10. The CS16 of the GCR plane may be used to repair the defective CS16 in CP10, and the CS48 of the GCR plane may be used to replace CS48 of CP09.

However, in memory devices with multiple storage modes, such as the examples described above, not all of the physical column select addresses may exist (e.g., address may not be assigned to a physical column select) in some or all of the storage modes. There is a risk that setting a swap bit to flip the most significant bit of the column select address may swap the column select with a column select that does not exist. Accordingly, improved techniques for swapping addresses for column selects within a column plane are needed to accommodate multiple storage modes.

According to embodiments of the present disclosure, multiple swap bits may be provided for column select addresses. In some embodiments, two swap bits may be provided. In some embodiments, the swap bits may permit swapping of the two most significant bits of the column select address. One or both of the swap bits may be set. Thus, the most significant bit, the next most significant bit, or both may be flipped. This may provide more flexibility for swapping column select addresses within a column plane. Having more options for swapping addresses may reduce or eliminate the risk of swapping a column select address to a column select address that does not exist/is not assigned. greater flexibility for swapping column select addresses within a column plane. In some applications, this may allow memory devices, including those configured to have multiple storage modes, to be repaired more often, which may increase yields.

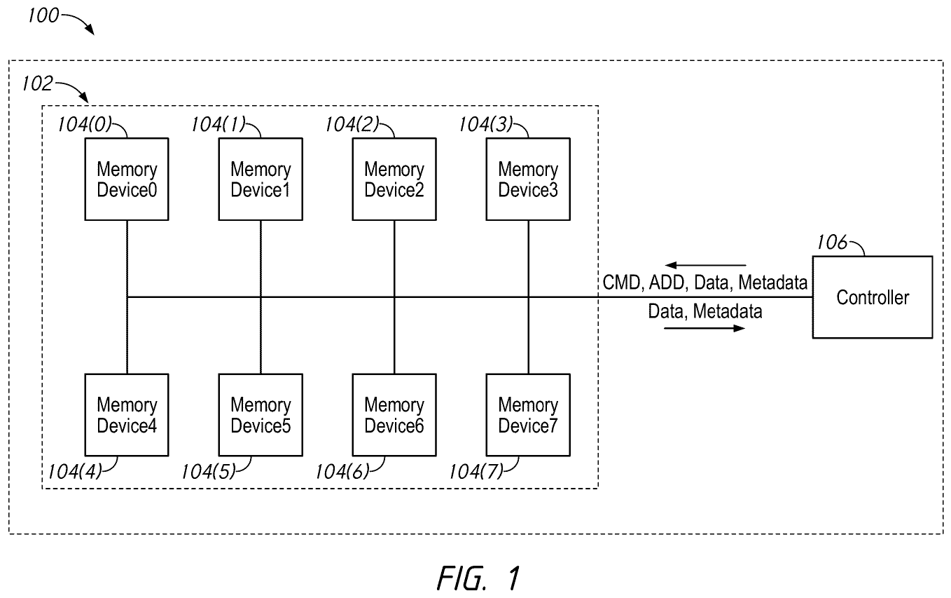

FIG. 1 is a block diagram of at least a portion of a computing system according to some embodiments of the present disclosure. The computing system 100 includes a memory module 102 and a controller 106 in communication with the memory module 102. In some embodiments, the controller 106 may be included in a processor (not shown) or in communication with the processor. The memory module 102 may include one or more memory devices 104. In the example shown in FIG. 1, there are eight memory devices 104(0-7). However, in other embodiments, there may be more or fewer memory devices (e.g., 4 devices, 16 devices). In some embodiments, additional memory devices 104 may be included to provide for redundancy. In some embodiments, memory module 102 may be a dual in-line memory module (DIMM). In some embodiments, what is shown in FIG. 1 may represent only half of the DIMM (e.g., one of the two channels). In other words, memory module 102 may include sixteen memory devices 104.

The controller 106 may provide commands, addresses, and/or data (e.g., data, metadata, or both) to one or more of the memory devices 104 and receive data from one or more of the memory devices 104. In some embodiments, memory devices 104 may be x4 or x8 memory devices. That is, either four or eight DQ terminals (e.g., pins) may be active. In some embodiments, the memory devices 104 may support both x4 and x8 operation. In some embodiments, whether the memory devices 104 operate in x4 or x8 mode may be based, at least in part, on values stored in mode registers (not shown in FIG. 1) of the memory devices 104. In some embodiments, the memory devices 104 may be x16 memory devices.

In some applications, each of the memory devices 104 may provide eight bits of metadata, for a total of four bytes of data. In some applications, each of the memory devices 104 may provide sixteen bits of metadata, for a total of eight bytes of data. The controller 106 may receive a prefetch from the memory devices 104 that include 128 bits of data and either 8 bits or 16 bits of metadata. In some embodiments, how much metadata is provided may be based on a value stored in the mode register of the memory device 104.

In some embodiments, whether or not metadata is stored at all may be based on a value stored in the mode register of the memory device 104. For example, when one value is stored in the mode register, 8 bits of metadata may be stored, when another value is stored in the mode register 16 bits of metadata may be stored, when a further value is stored in the mode register, metadata may not be stored. When this value is stored, all of the column selects are available for providing data to and from the array. Thus, a same memory may be utilized for applications where different amounts of metadata are desired was well as applications where metadata is not desired.

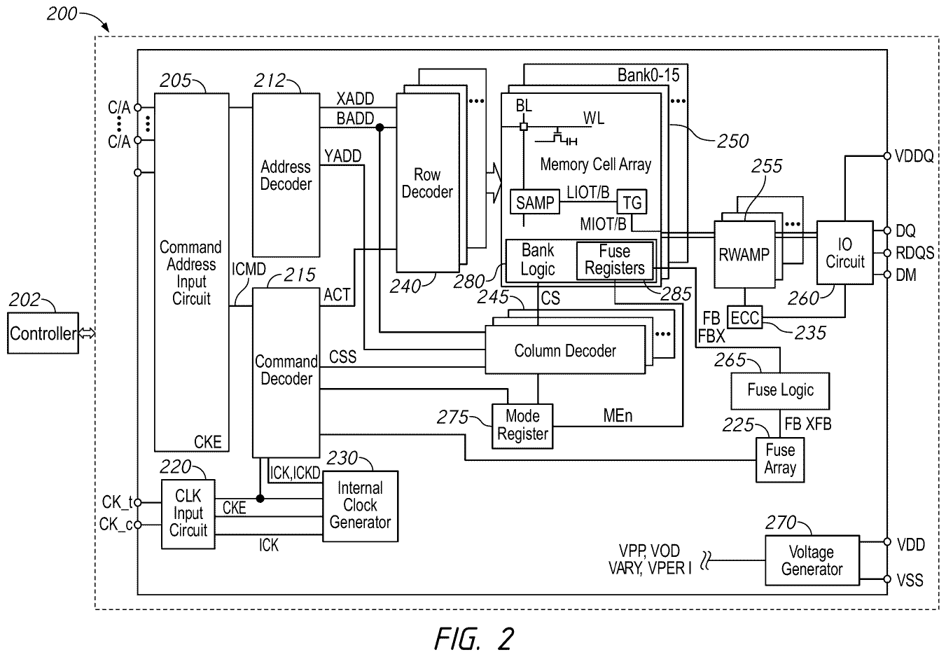

FIG. 2 is a block diagram of a semiconductor device according to some embodiments of the present disclosure. The apparatus may be a semiconductor device, which may be a memory device 200, and will be referred as such. In some embodiments, the memory device 200 may include, without limitation, a dynamic random access (DRAM) device integrated into a single semiconductor chip. In some examples, the DRAM may be a double data rate (DDR) memory. In some embodiments, one or all of the memory devices 104(0-7) of FIG. 1 may include memory device 200.

The memory device 200 may be included on a die. The die may be mounted on an external substrate, for example, a memory module substrate, a mother board or the like (e.g., package-on-package (PoP)). The memory device 200 may include a memory array 250. The memory array 250 includes a plurality of banks BANK0-15, each bank including a plurality of word lines WL, a plurality of bit lines BL, and a plurality of memory cells MC arranged at intersections of the plurality of word lines WL and the plurality of bit lines BL. Although sixteen banks are shown in FIG. 2, memory array 250 may include any number of banks. The banks may include bank logic circuit 280, which may include various circuit components for operation of the bank. In the embodiment shown, the bank logic circuit 280 includes fuse registers 285. The fuse registers 285 may include latches that store information related to logical addresses remapped to redundant memory lines.

The selection of the word line WL is performed by a row decoder 240 and the selection of the bit line BL is performed by a column decoder 245. Sense amplifiers (SAMP) are located for their corresponding bit lines BL and connected to at least one respective local I/O line pair (LIOT/B), which is in turn coupled to at least respective one main I/O line pair (MIOT/B), via transfer gates (TG), which function as switches. The TG may be coupled to one or more read/write amplifiers (RWAMP) 255, which may be coupled to an error correction code (ECC) circuit 235. The ECC circuit 235 may be coupled to an IO circuit 260, which may be coupled to one or more external terminals of memory device 200. Read data from the bit line BL is amplified by the sense amplifier SAMP, and transferred to read/write amplifiers 255 over complementary local data lines (LIOT/B), transfer gate (TG), and complementary main data lines (MIOT/B) to the ECC circuit 235. Conversely, write data outputted from the ECC circuit 235 is transferred to the sense amplifier SAMP over the complementary main data lines MIOT/B, the transfer gate TG, and the complementary local data lines LIOT/B, and written in the memory cell MC coupled to the bit line BL.

The memory device 200 may employ a plurality of external terminals that include command and address terminals coupled to a command/address (C/A) bus to receive command and address signals, clock terminals to receive clock signals CK_t and CK_c, data terminals DQ, RDQS, and power supply terminals VDD, VSS, VDDQ, and VSSQ.

The C/A terminals may be supplied with an address and a bank address signal from outside, for example, from a controller 202. The address signal and the bank address signal supplied to the address terminals are transferred, via a command/address input circuit 205, to an address decoder 212. The address decoder 212 receives the address signals and supplies a decoded row address signal XADD to the row decoder 240, and a decoded column address signal YADD to the column decoder 245. The address decoder 212 also receives the bank address signal BADD and supplies the bank address signal to the row decoder 240 and the column decoder 245.

The C/A terminals may further be supplied with command signals from, for example, a controller 202. In some embodiments, controller 202 may be implemented or included in controller 106. The command signals may be provided as internal command signals ICMD to a command decoder 215 via the command/address input circuit 205. The command decoder 215 includes circuits to decode the internal command signals ICMD to generate various internal signals and commands for performing operations, for example, a row activation signal (ACT) to select a word line. Another example may be providing internal signals to enable circuits for performing operations, such as control signals to enable signal input buffers that receive clock signals.

Each bank BANK0-15 may be organized into multiple physical column planes (CP). Each column plane may be associated with multiple column selects (e.g., CS0-63, CS0-59, CS0-55). In some embodiments, different column planes may be used to store different types of information. For example, some column planes may store data and another plane stores ECC data. Optionally, a further plane may store GCR data. According to embodiments of the present disclosure, the array 250 can be selectively configured to utilize one or more column planes to store metadata. Depending on a storage mode, some column planes may store data while one or more column planes store metadata, or all of the column planes may store data. For example, in a first mode, two column planes may store metadata and the remaining planes store data. In a second mode, one column plane stores metadata and the remaining planes store data. In a third mode, all of the column planes store data. A separate plane may store ECC data in some embodiments. In some embodiments, the column planes may include additional column selects (redundant column selects) for repairing defective column selects in the corresponding planes. In some embodiments, each bank may include an additional GCR plane with redundant column selects available to repair defective column selects in any of the column planes of the bank. In some embodiments, the GCR may have fewer column selects than other column planes (e.g., 8, 16, 32).

The C/A terminals may receive an access command which is a read command. When a read command is received, and a bank address, a row address and a column address are timely supplied with the read command, a codeword including read data, metadata, and read ECC data (e.g., parity bits) is read from memory cells in the memory array 250 corresponding to the row address and column address. The read command is received by the command decoder 215, which provides internal commands so that read data from the memory array 250 is provided to the ECC circuit 235. The ECC circuit 235 may use the parity bits in the codeword to determine if the codeword includes any errors, and if any errors are detected, may correct them to generate a corrected codeword (e.g., by changing a state of the identified bit(s) which are in error). The corrected codeword (without the parity bits) is output from the data terminals DQ via the input/output circuit 260.

The C/A terminals may receive an access command which is a write command. When the write command is received, and a bank address, a row address, and a column address are timely supplied as part of the write operation, and write data is supplied through the DQ terminals to the ECC circuit 235. The write data (which may include write data and metadata) supplied to the data terminals DQ is written to a memory cells in the memory array 250 corresponding to the row address and column address. The write command is received by the command decoder 215, which provides internal commands so that the write data is received by data receivers in the input/output circuit 260. The write data is supplied via the input/output circuit 260 to the ECC circuit 235. The ECC circuit 235 may generate ECC data (e.g., a number of parity bits) based on the write data, and the write data and the parity bits may be provided as a codeword to the memory array 250 to be written into the memory cells MC.

The ECC circuit 235 may be used to ensure the fidelity of the data read from a particular group of memory cells to the data written to that group of memory cells. The memory device 200 may include a number of different ECC circuits 235, each of which is responsible for a different portion of the memory cells MC of the memory array 250. For example, there may be one or more ECC circuits 235 for each bank of the memory array 250. Typically, each bank BANK0-15 includes a column plane for the storage of ECC data (e.g., parity bits) and additional column planes for the storage of data (e.g., sixteen column planes). In these applications, the ECC circuit 235 generates eight bits of ECC data (e.g., 8 bits of ECC data) for each prefetch of 128 bits. This may allow for the ECC circuit 235 to provide single bit error correction.

The command decoder 215 may access mode register 275 that is programmed with information for setting various modes and features of operation for the memory device 200. For example, the mode register 275 may provide parameters that allow the memory device 200 to operate at different frequencies, provide different burst lengths, allow banks BANK0-15 to be organized into different groups, operate in x4, x8, or x16 mode, and/or other different operating conditions. In some embodiments, mode register 275 may include multiple registers.

The information in the mode register 275 may be programmed by providing the memory device 200 a mode register write command, which causes the memory device 200 to perform a mode register write operation. In some embodiments, data to be written to the mode register 275 is provided via the C/A terminals and/or the DQ terminals. The command decoder 215 accesses the mode register 275, and based on the programmed information along with the internal command signals provides the internal signals to control the circuits of the memory device 200 accordingly. Information programmed in the mode register 275 may be externally provided by the memory device 200 using a mode register read command, which causes the memory device 200 to access the mode register 275 and provide the programmed information (e.g., to the memory controller 202). In some embodiments, the information may be provided via the C/A terminals and/or the DQ terminals.

The mode register 275 may be programmed with a value that determines an amount of metadata stored in the memory device 200. When one value is stored in the register, no metadata may be stored (e.g., an operating mode where metadata is disabled). When another value is stored in the register, an amount of metadata may be stored, and when a further value is stored in the register, a different amount of metadata may be stored (e.g., operating modes where metadata is enabled). For example, the memory device 200 may have a mode where 16 bits of metadata are stored per prefetch (MD16 ON), a mode where 8 bits of metadata are stored per prefetch (MD8 ON), and a mode where no metadata is stored (MD OFF).

Based on the values stored in the mode register 275, the mode register may provide one or more signals to the column decoder 245. In some embodiments, the signals from the mode register 275 may determine which column select signals are activated and/or physical column planes are accessed during an access operation (e.g., read or write operations). Selectively activating or suppressing column select signals associated with one or more physical column planes may allow the formation of virtual column planes. This may allow the memory device 200 to appear to the controller 202 to have a number of column planes different than a number of physical column planes in the array 250.

The memory device 200 may include a fuse array 225, which contains non-volatile storage elements which may store information about addresses in the memory array 250. The fuse array 225 includes non-volatile storage elements, such as fuses or anti-fuses. Each fuse may be in a first state where it is conductive and may be ‘blown’ to make the fuse insulating instead. Each anti-fuse may be in a first state which is non-conductive, until it is blown to make the anti-fuse conductive instead. Each fuse/anti-fuse may permanently change when it is blown. Each fuse/anti-fuse may be considered to be a bit, which is in one state before it is blown, and permanently in a second state after it's blown. For example, a fuse may represent a logical low before it is blown and a logical high after it is blown, while an anti-fuse may represent a logical high before it is blown and a logical low after it is blown. Discussions of fuses as used herein may generally refer to either fuses or anti-fuses and that embodiments may use fuses, anti-fuses, or a combination thereof in the fuse array 225. In some embodiments, the fuse array 225 may be programmed by the command decoder 215. The command decoder 215 may program the fuse array 225 based on commands and address information provided by an external device. For example, the external device may be the controller 202 in some embodiments. In another example, the external device may be a testing device.

Specific groups of fuses/anti-fuses may be represented by a fuse bus address (FBA), which may specify the physical location of each of the fuses/anti-fuses in the group within the fuse array 225. The group of fuses/anti-fuses associated with a particular FBA may in turn be used to encode an address associated with one or more memory cells of the memory array 250 when the memory device 200 is in a default storage mode. For example, the state of a group of fuses/anti-fuses may represent a memory line address (e.g., either a row address XADD or a column address YADD). The address and/or shift information in the fuse array 225 may be broadcast out along a fuse bus (FB and xFB) to fuse registers 285.

Each fuse register 285 may be associated with a particular memory line of the memory array 250. In some embodiments, only the redundant memory lines of the memory array 250 (e.g., the rows/columns designated for use in repair operations) may be associated with one of the fuse registers 285. The address and/or shift information stored in a given group of fuses/anti-fuses (e.g., a group specified by an FBA) may be broadcast from the fuse array 225 along the fuse bus and may be latched by a particular fuse register 285. The fuse logic circuit 265 may determine which address broadcast along the fuse bus is latched in which fuse register 285. In this manner, an address stored in the fuse array 225 may be associated with a particular memory line of the memory array 250. When an incoming row/column address XADD or YADD matches the address stored in the fuse register 285, it may then direct access commands to the memory line associated with that fuse register 285.

The fuse registers 285 may each contain a number of fuse latches, each of which stores a bit of the stored memory line address and/or shift information. Since row addresses XADD and column addresses YADD may be different lengths, fuse registers 285 associated with redundant rows may have a different number of fuse latches than fuse registers 285 associated with redundant columns. Each of the fuse registers 285 may be coupled to a fuse match circuit in the bank logic circuit 280, which compares the incoming memory line address as part of an access operation to the address stored in the fuse register 285 to determine if there is a match. If there is a match, the redundant memory line associated with the fuse register 285 may be activated. Some components of the match circuits, as well as other control logic of the fuse registers 285 may be shared between multiple fuse registers 285.

Additionally or alternatively, the fuse registers 285 may include or be replaced with fuse banks, that is, non-volatile storage elements as used in fuse array 225. In some embodiments, the fuse banks 285 may be utilized instead of the centralized fuse array 225, which may reduce or eliminate the need for broadcast operations. Although the fuse registers/banks 285 are shown in the bank logic circuit 280, in some embodiments, the fuse registers/banks 285 may be located in a peripheral area outside the banks of the array 250 separate from bank logic circuit 280. For example, the fuse registers/banks 285, at least a portion of the match circuits and/or other control logic may be located in the peripheral area, and the fuse registers/banks 285 may provide information to the bank logic circuit 280 of the appropriate bank of the array 250.

Although the fuse registers 285 are shown in the bank logic circuit 280, in some embodiments, the fuse registers 285 may be located in a peripheral area outside the banks of the array 250 separate from bank logic circuit 280. For example, the fuse registers 285, at least a portion of the match circuits and/or other control logic may be located in the peripheral area, and the fuse registers 285 may provide information to the bank logic circuit 280 of the appropriate bank of the array 250. While the column decoder 245 for each bank is shown separate from the bank logic circuit 280 and fuse registers 285 of each bank, in some embodiments, some of the bank logic circuit 280 components and/or fuse registers 285 may be included in the column decoder 245 or vice vera. For example, portions of or all of matching circuits, multiplexers for redirecting activation of column select signals and/or data from columns, or combinations thereof, may be included in the column decoder 245 in some embodiments. Further, while for clarity column decoder 245 is shown spaced apart from the memory array 250 and bank logic circuit 280, in some embodiments the column decoder 245 may be adjacent thereto or integrated as previously described.

According to embodiments of the present disclosure, the fuse array 225 and/or fuse registers/banks 285 may store multiple swap bits associated with individual column planes of each memory bank BANK0-15. In some embodiments, the swap bits may be set to selectively flip one or more of the most significant bits of a column select address. In some embodiments, the swap bits may be used to selectively flip one or both of the two most significant bits of the column select address. When stored in the fuse array 225, the swap bit information may be provided to the fuse registers 285 during a broadcast operation. When stored in the fuse bank 285, the broadcast operation may not be used.

Turning to the explanation of the external terminals included in the memory device 200, the clock terminals and data clock terminals are supplied with external clock signals and complementary external clock signals. The external clock signals CK_t, CK_c may be supplied to a clock input circuit 220. When enabled, input buffers included in the clock input circuit 220 pass the external clock signals. For example, an input buffer passes the CK_t and CK_c signals when enabled by a CKE signal from the command decoder 215. The clock input circuit 220 may use the external clock signals passed by the enabled input buffers to generate internal clock signal ICK. The internal clock signal ICK are supplied to internal clock circuit 230 for providing one or more clock signals to the various components of memory device 200.

The internal clock circuits 230 includes circuits that provide various phase and frequency controlled internal clock signals based on the received internal clock signals. For example, the internal clock circuits 230 may include a clock path (not shown in FIG. 2) that receives the ICK clock signal and provides internal clock signals ICK and ICKD to the command decoder 215. Optionally, the input/output circuit 260 may include clock circuits and driver circuits for generating and providing the RDQS signal to a controller.

The power supply terminals are supplied with power supply potentials VDD and VSS. These power supply potentials VDD and VSS are supplied to an internal voltage generator circuit 270. The internal voltage generator circuit 270 generates various internal potentials VPP, VOD, VARY, VPERI, and the like and a reference potential ZQVREF based on the power supply potentials VDD and VSS. The internal potential VPP is mainly used in the row decoder 240, the internal potentials VOD and VARY are mainly used in the sense amplifiers included in the memory array 250, and the internal potential VPERI is used in many other circuit blocks.

The power supply terminal is also supplied with power supply potential VDDQ. The power supply potentials VDDQ is supplied to the input/output circuit 260 together with the power supply potential VSS. The power supply potential VDDQ may be the same potential as the power supply potential VDD in an embodiment of the disclosure. The power supply potential VDDQ may be a different potential from the power supply potential VDD in another embodiment of the disclosure. However, the dedicated power supply potential VDDQ is used for the input/output circuit 260 so that power supply noise generated by the input/output circuit 260 does not propagate to the other circuit blocks.

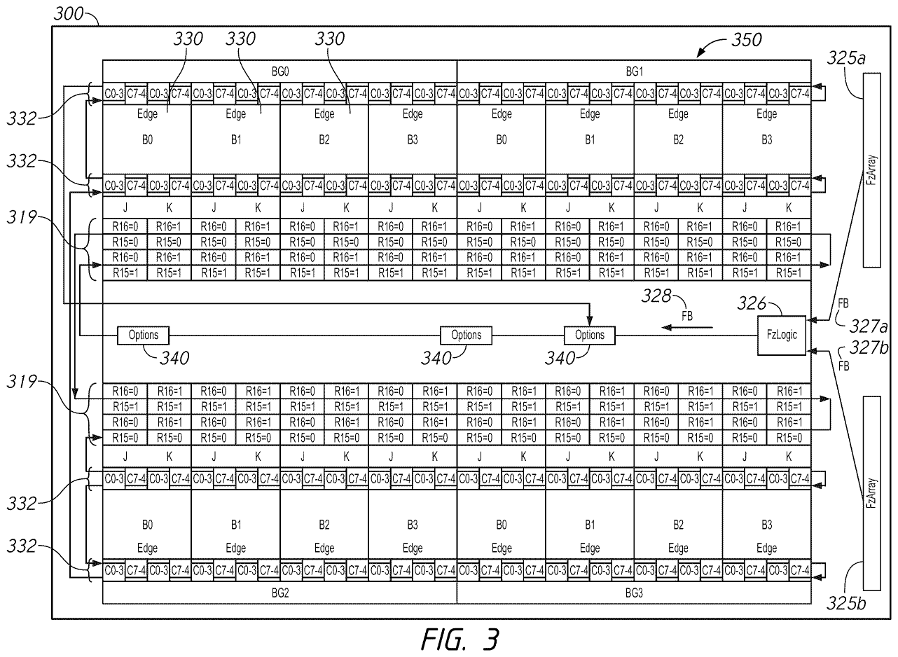

FIG. 3 is a block diagram of a portion of a memory device according to some embodiments of the present disclosure. The memory device 300 may, in some embodiments, represent a portion of the memory device 200 of FIG. 2 and/or a portion of one or more of the memory devices 104 in FIG. 1. FIG. 3 shows a portion of a memory array 310-316 and 320-326 and redundancy circuitry 336 which may be part of a memory bank (e.g., BANK0-15 of FIG. 2) along with selected circuits used in the data path such as the ECC circuit 332 (e.g., 235 of FIG. 2) and IO circuits 334 (e.g., 260 of FIG. 2). For clarity certain circuits and signals have been omitted from the view of FIG. 3.

The memory device 300 is organized into a number of column planes 310-316. Each of the column planes represents a portion of a memory bank. Each column plane 310-316 includes a number of memory cells at the intersection of word lines WL and bit lines. The bit lines may be grouped together into sets which are activated by a value of a column select (CS) signal. For the sake of clarity, only a single vertical line is used to represent the bit lines of each column select set, however, there may be multiple columns accessed by that value of CS. For example, each line may represent eight bit lines, all accessed in common by a value of CS. As used herein, a ‘value’ of CS may refer to a decoded signal provided to sets of bit lines (e.g., from a column decoder such as 245 in FIG. 2). A first value may represent a first value of a multibit CS signal, or after decoding a signal line associated with that value being active. The word lines may be extended across multiple of the column planes 310-316.

The memory device 300 includes a set of column planes 310 that store data and column planes 316 that stores metadata. The memory device 300 may include an ECC column plane 312 to store ECC information, such as error correction parity bits. The memory device 300 may include a global column redundancy (GCR) column plane 314. In some embodiments, the GCR column plane 314 may have fewer memory cells (e.g., fewer column select groups) than the data column planes 310. The GCR CP 314 includes a number of redundant columns which may be used as part of a repair operation. If a value of the CS signal is identified as including defective memory cells in one of the data column planes 310, then the memory may be remapped such that the data which would have been stored in that column plane for that value of CS is instead stored in the GCR CP 314.

In the example shown in FIG. 3, the memory device 300 may include 16 data column planes 310(0)-310(15) and two metadata column planes 316(0)-316(1). Some of the data and metadata planes may have 56 CS and others of the data and metadata planes may have 60 CS (e.g., total of 1024 column selects). Each set of column select includes 8 bit lines.

When the memory device 300 is in an operating mode where both metadata planes 316 are utilized for storing metadata, when a word line is opened responsive to a row address, and a column select signal is provided to each of the 18 column planes then 8 bits are accessed from each of the 18 column planes for a total of 144 bits (128 data bits and 16 metadata bits). A column select signal is also provided to the ECC column plane 312, although that column select signal may be a different value than the one provided to the column planes 310 for an additional 8 bits. If a repair has been performed, the GCR CP 314 may also be accessed and the value on a GCR LIO may be used while ignoring the LIO of the column plane it is replacing. Accordingly, the maximum number of bits that can be retrieved as part of an access pass is 128 bits from the data column planes 310 (with 8 bits substituted from the GCR CP 314 if there has been a repair) along with 16 bits from the metadata column planes 316 and 8 additional bits from the ECC CP 312.

During read operations, data may be provided from the column planes 310 to the sense amplifiers 320 to the ECC circuit 332. Metadata may be provided from column planes 316 to sense amplifiers 326 and ECC data may be provided from column plane 312 to sense amplifier 322 to the ECC circuit 332. (If a repair has been made, data may also be provided from column plane 314 to sense amplifier 324 to the ECC circuit 332.) The ECC circuit 332 may use the ECC data provided from column plane 312 to correct and/or detect errors in the data and/or metadata. The ECC circuit 332 may output the data and metadata (corrected, if needed) to the I/O circuit 334. The I/O circuit 334 may provide the data and metadata to the DQ. The DQ may make the data and metadata to an external device (e.g., a controller such as 106 in FIGS. 1 and/or 202 in FIG. 2). Optionally, the ECC circuit 332 may further provide error information for output on the DQ.

During write operations, data and metadata may be received by the I/O circuit 334 from the DQ and provide the data and metadata to the ECC circuit 332. Optionally, error information may also be received and provided to the ECC circuit 332. The ECC circuit 332 may generate parity bits and/or other error correction information for the data and metadata. The ECC circuit 332 may provide the data to sense amplifiers 320 for storage in column planes 310. Metadata may be provided to sense amplifiers 326 for storage in column planes 316 and the error correction information may be provided to sense amplifier 322 for storage in column plane 312. (If a repair has been made, data may also be provided from the ECC circuit 332 to sense amplifier 324 for storage in column plane 314.)

When the memory device 300 is in an operating mode that uses only one of the metadata planes 316 to store metadata, the other one of the metadata planes 316 may be used to store data instead of metadata. As described herein, the activation of the column selects may be modified to form virtual planes from the column planes 310 and one of the metadata planes 316. When the memory device 300, is in an operating mode where the memory device 300 does not store metadata, the activation of the column selects may be modified to form virtual planes from column planes 310 and both metadata planes 316. The number of virtual planes may be equal to the number of data column planes 310 in some embodiments. Each virtual plane may be associated with 64 CS addresses. This may allow a controller to receive an expected amount of data from the memory device 300 for a prefetch.

Remapping addresses of defective column selects from column planes 310, 316, and/or 312 to column selects in the GCR CP 314 may be performed by redundancy circuitry 336. In addition to remapping addresses of defective column selects to the GCR CP 314, the redundancy circuitry 336 may change addresses assigned to column selects within column planes. The redundancy circuitry 336 may be included in bank logic circuit 280 in some embodiments. The redundancy circuitry 336 may include multiplexers or other circuit components that allow data to and from the memory array to be rerouted. The settings of the multiplexers or other circuit components may be controlled, at least in part, by data stored in fuses and/or fuse registers, for example, fuse array 225 and fuse registers/banks 285 of FIG. 2. For remapping column selects to the GCR CP 314, the fuses and/or fuse registers may store column addresses of the defective column selects.

As noted above, some physical column planes have 56 or 60 column selects, but virtual planes are associated with 64 column selects. Thus, up to 8 column select addresses for a virtual plane may not exist for a physical column plane. In some applications, this may cause issues when column select addresses are swapped. Typically, only one swap bit was provided, so only the most significant bit of the address could be swapped. However, this could cause the address to be swapped to a physical column select that does not exist in the physical column plane.

According to embodiments of the present disclosure, for swapping addresses between column selects in a same column plane, the fuses and/or fuse registers may store two or more swap bits. In some embodiments, the swap bits may flip the most significant bit, the second most significant bit, or both in order to change the physical column select in the same physical column plane associated with the logical address. In some embodiments, the swap bits may be set during testing of the memory device 300. In some embodiments, the swap bits may be set during a post package repair operation. The swap bits may be set by providing commands from an external device (e.g., controller 206 and/or controller 106 or a testing device).

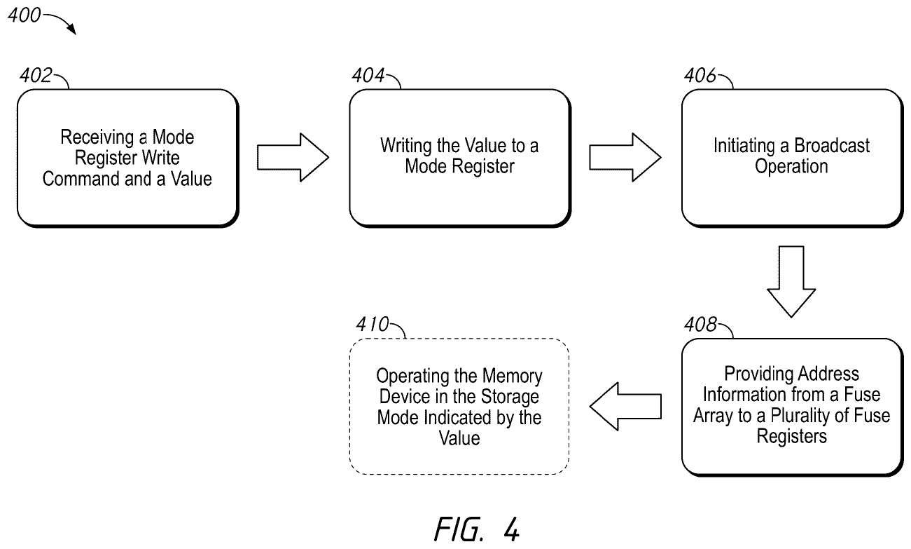

FIG. 4 shows a table indicating organization of the bank of the memory array and physical column plane suppression scheme according to some embodiments of the present disclosure. The organization depicted in table 400 may be used when a memory device (e.g., one or more of memory devices 104, memory device 200, and/or memory device 300) is in an operating mode where no metadata is stored (MD OFF).

The top row of table 400 indicates the number of column selects (#CS) associated with each physical plane. The row just below indicates the physical column planes (CP). There is a total of 1,024 CS for data and metadata column planes. In the example shown in FIG. 4, 56 physical CS are associated with data CP0, CP2-7, CP9-14, and metadata MD1. Sixty physical CS are associated with data CP1, CP15, and metadata MD0. In other examples, different column planes may be assigned 60 CS and different column planes may be assigned 56 CS. Sixty-four CS are associated with the ECC data plane ECC, and 16 CS are associated with the global column redundancy plane GCR. Other arrangements of the memory array may be used, such as those described in U.S. patent application Ser. Nos. 18/916,497 and 18/916,521.

Below the top two rows are several columns providing more details on the organization of the data in the memory array. The first column indicates the column selects (CS) addresses. The vertical bars separating columns indicate the locations of subword line drivers (SWD0-10) relative to the physical column planes. The remaining columns of table 400 indicate the column (CS) addresses associated with the physical column planes. For the data and metadata column planes, certain column selects are not assigned because only 56 or 60 CS are assigned to the physical column planes.

When no metadata is stored in the memory device, more space in the memory array is available for storing data. However, because of the allocation of the column selects, additional data cannot be stored in the physical data column planes. Rather, the additional data is stored in the metadata planes MD0 and MD1. In order for a controller (e.g., controller 106, controller 202) to receive the number of data bits expected (e.g., 128 data bits) in a prefetch, the activation of the column selects are adjusted to form 16 virtual data planes (virtual planes) each associated with 64 CS. In the example shown, physical MD0 “lends” its column select signals to virtual data plane CP7. MD1 “lends” its column select signals to virtual data plane CP8. The remaining physical data CP are arranged into the virtual planes. For example, physical CP1 includes physical column selects assigned to virtual plane CP1 and virtual plane CP0. In another example, physical CP9 includes column selects assigned to virtual planes CP9 and CP10.

During operation, the column select signals for one or more physical column planes may be suppressed and/or not assigned. In the example shown in FIG. 4, column select addresses associated with two physical planes may not be activated. The shaded boxes in table 400 indicate the column selects of a physical plane that are suppressed during a memory access operation/not assigned. For example, say one of CS11:4 is activated (e.g., by a column decoder, such as 245 in FIG. 2). For virtual plane CP7, the data associated with CS11:4 is located in physical MD0, not in physical plane CP7. Accordingly, CS11:4 of physical plane CP7 are not assigned/activated as indicated by the shaded boxes. Similarly, virtual plane CP14 is formed by column selects from physical planes CP13 and CP14. When CS11:4 are activated, no column selects in physical plane CP14 are activated.

As shown in FIG. 4, for each set of 4 or 8 column select signals, two physical column planes are suppressed during an access operation, forming suppressed “pairs” (e.g., MD0 and CP15, CP7 and CP14, CP6 and CP13, etc.). Thus, for a given column address, a pair of physical column planes will have a same set of addresses and missing (e.g., suppressed) address space. When only a single swap bit is available, this may give rise to a case where the came column address can be bad in a pair of physical planes, and the swap bit maps into the address which is not present in the column planes. For example, if CS52 goes bad in both physical CP5 and physical CP12, CS52's address is “110100.” If the swap bit is set for CP5 or CP12, CS52 is remapped to “010100,” which corresponds to CS20. However, as shown in FIG. 4, CS20 does not exist for CP5 and CP12. Accordingly, CS52 will be remapped to a suppressed/unassigned address.

According to embodiments of the present disclosure, two swap bits may be provided instead of just one. For example, the two most significant bits may be swapped by two swap bits. In this example, CS52 may be remapped to “000100,” which corresponds to CS4 or “100100” which corresponds to CS36, both of which exist and are not suppressed in physical CP5 and CP12. Thus, providing multiple swap bits allows for more flexibility for remapping column select signals within a plane. This allows a memory device configured to have multiple storage modes to be repaired in more scenarios.

Although the examples provided herein describe the multiple swap bits as being the two most significant bits, other combinations of bits of the column select address may be flipped by the swap bits. Which bits are selected to be flippable by the swap bits may be based on the organization of the memory array and/or the organization of the memory array in one or more storage modes. In some embodiments, more than two swap bits may be provided. While more than two swap bits may provide even more flexibility, this advantage may be offset by the increase in the number of fuses required for the swap bits, depending on the organization of the memory array.

In some embodiments, the swap bits may be set during testing and repair of the memory device during manufacturing (e.g., prior to being packaged, prior to being provided to a customer). In some embodiments, the swap bits may be set during a post-package repair operation. The swap bits may be set by sending commands to the memory device (e.g., to a command decoder) from an external device in some embodiments. For example, a controller or testing equipment may provide commands that cause the memory device to set the fuses to set the desired swap bits. In other embodiments, the fuses may be set manually by testing and/or repair equipment prior to packaging of the memory device.

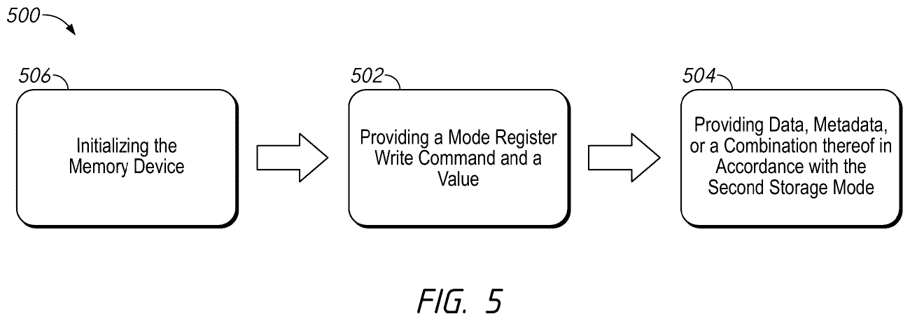

FIG. 5 is a flow chart of a method according to some embodiments of the present disclosure. In some embodiments, the method shown in flow chart 500 may be performed in whole or in part by a memory device, such as one or more of memory devices 104, memory device 200, and/or memory device 300.

At block 502 “receiving, at a memory device, a command indicating one or more of a plurality of swap bits to set” may be performed. Responsive to the command, “programming one or more of a plurality of fuses to set the one or more of the plurality of swap bits” may be performed as indicated by block 504. In some embodiments, the fuses may be included in a fuse array, such as fuse array 225. In these embodiments, the method in flow chart 500 may further include “broadcasting the plurality of swap bits from the plurality of fuses to a fuse register.” In some embodiments, the fuses may be included in a fuse bank, such as fuse bank 285. In some embodiments, the programming comprises setting two of the plurality of fuses to flip two bits of the address. In some embodiments, the two bits comprise two most significant bits of the address.

Responsive to programming the one or more of the plurality of fuses, “remapping an address from a first column select of a column plane to a second column select of the column plane” may be performed at block 506.

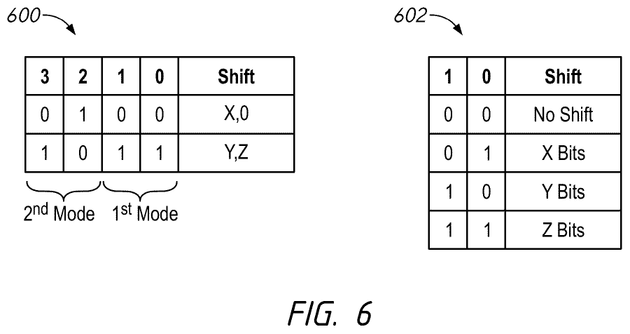

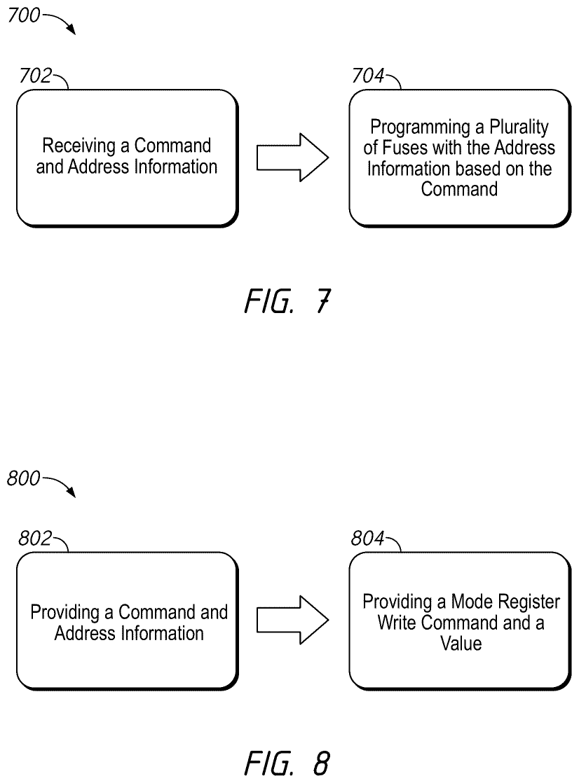

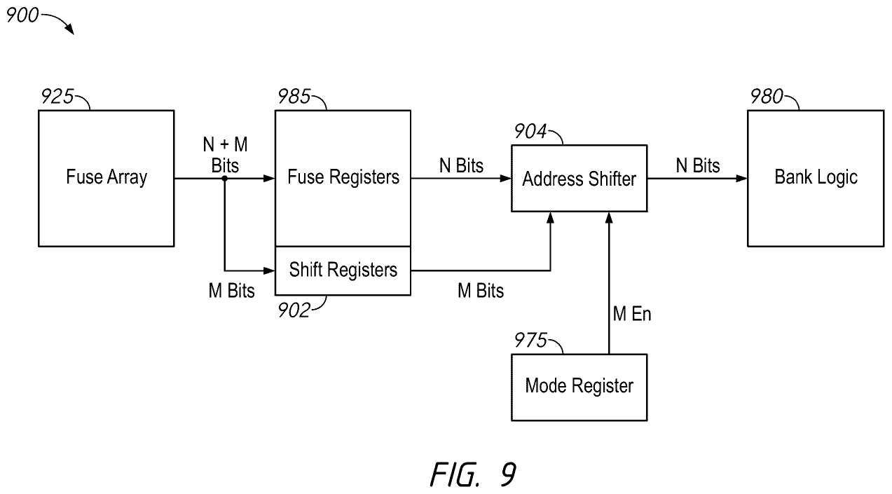

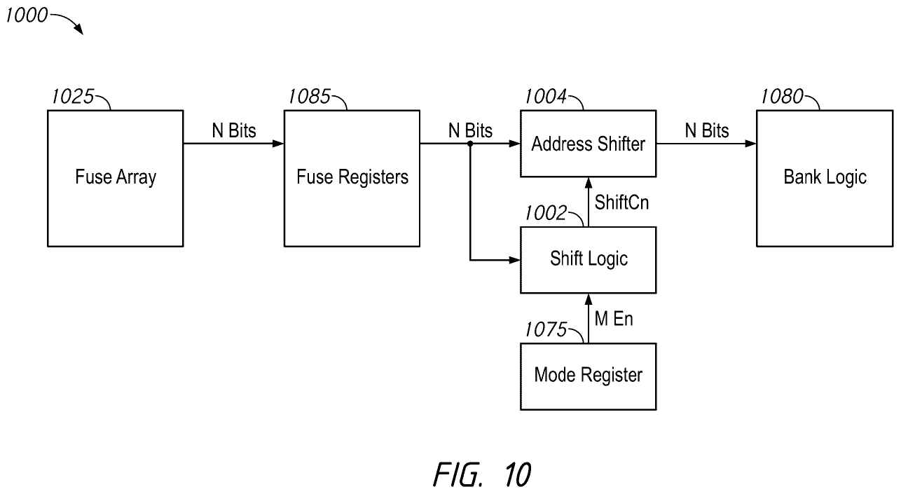

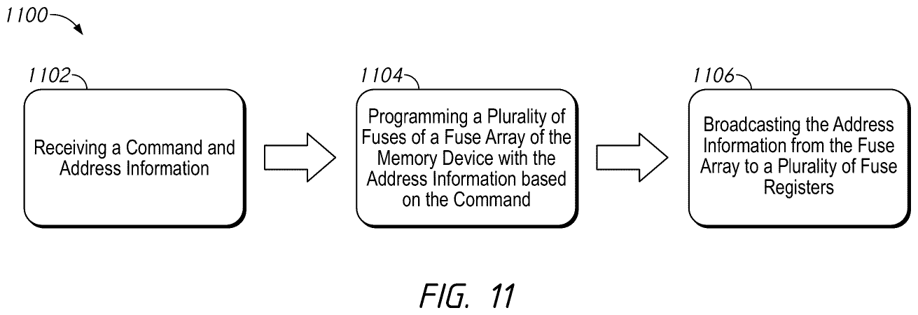

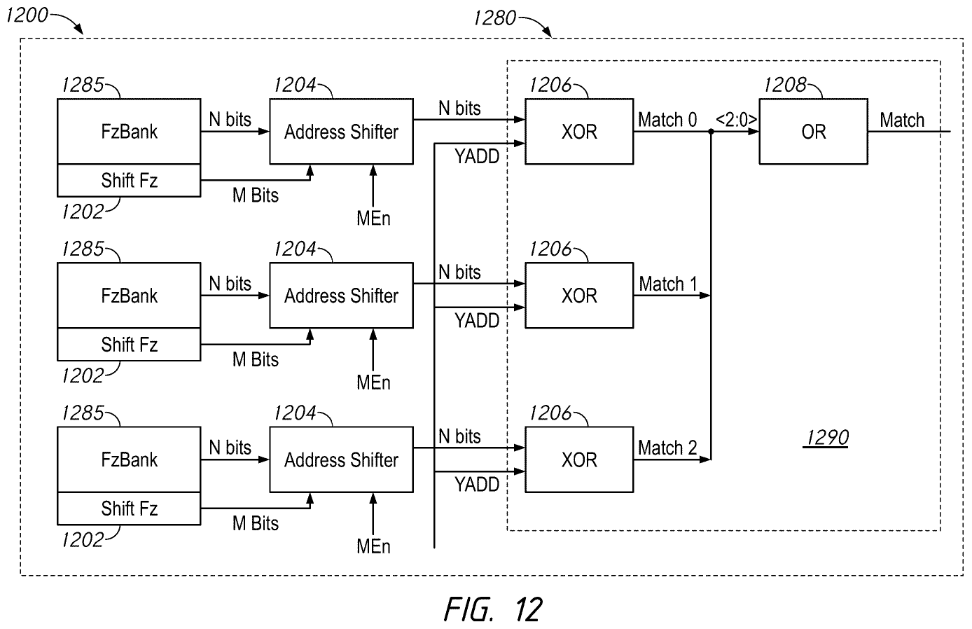

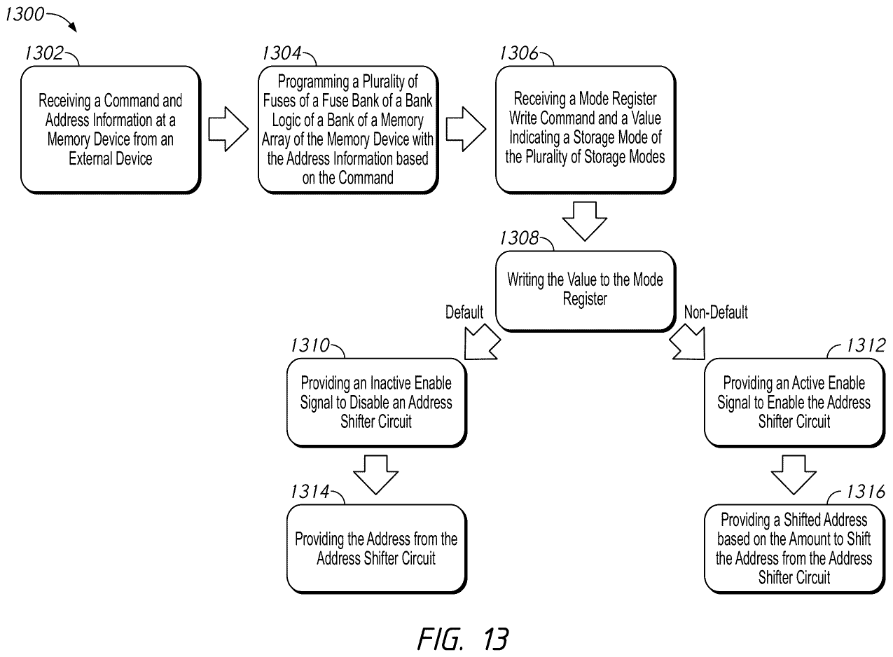

FIG. 6 is a flow chart of a method according to some embodiments of the present disclosure. In some embodiments, the method shown in flow chart 600 may be performed in whole or in part by a testing device or a controller, such as controller 106 and/or controller 202.

At block 602, “providing to a memory device, a command indicating one or more of a plurality of swap bits to set.” In some embodiments, this may cause the memory device to set the swap bits by programming one or more fuses of the memory device to cause the memory device to remap an address from a first column select of a column plane to a second column select of the column plane of a memory array of the memory device.

Optionally, the method in flow chart 600 may further include block 604 where “testing the memory device” may be performed. Responsive to the testing, at block 606 “determining the first column select is defective” may be performed. In some embodiments, the command is provided responsive to the determining the first column select is defective.

Apparatuses, methods, and systems disclosed herein may provide a memory array that provides greater flexibility for swapping column select addresses within a column plane. This may reduce or prevent column select addresses from being remapped to column select addresses that are not assigned and/or do not exist. In some applications, this may allow memory devices configured to have multiple storage modes to be repaired more often, which may increase yields.

Of course, it is to be appreciated that any one of the examples, embodiments or processes described herein may be combined with one or more other examples, embodiments and/or processes or be separated and/or performed amongst separate devices or device portions in accordance with the present systems, devices and methods.

Finally, the above discussion is intended to be merely illustrative of the present system and should not be construed as limiting the appended claims to any particular embodiment or group of embodiments. Thus, while the present system has been described in particular detail with reference to exemplary embodiments, it should also be appreciated that numerous modifications and alternative embodiments may be devised by those having ordinary skill in the art without departing from the broader and intended spirit and scope of the present system as set forth in the claims that follow. Accordingly, the specification and drawings are to be regarded in an illustrative manner and are not intended to limit the scope of the appended claims.

What is claimed is:

1. An apparatus comprising:
a bank of a memory array having a column plane including a first column select signal and a second column select signal; and
a plurality of fuses configured to store a corresponding plurality of swap bits, wherein the plurality of swap bits are configured to be set to map the first column select signal to an address of the second column select signal.

2. The apparatus of claim 1, wherein a number of the plurality of swap bits is two.

3. The apparatus of claim 1, wherein the plurality of swap bits are configured to flip a corresponding number of most significant bits of the address when set.

4. The apparatus of claim 1, further comprising a fuse array including the plurality of fuses.

5. The apparatus of claim 4, further comprising a fuse register configured to receive and store the plurality of swap bits from the fuse array.

6. The apparatus of claim 1, further comprising a fuse bank including the plurality of fuses.

7. The apparatus of claim 1, wherein the bank further comprises a global column redundancy (GCR) plane comprising a plurality of column select signals, and
the apparatus further comprises a second plurality of fuses configured to be set to map the second column select signal to a column select of the plurality of column select signals of the GCR plane.

8. The apparatus of claim 1, wherein the bank is configured to be arranged in one of a plurality of storage modes.

9. The apparatus of claim 8, wherein each of the plurality of storage modes stores a different amount of metadata.

10. A system comprising:
a memory device including:
a memory array having a physical column plane including a first column select signal and a second column select signal; and
a plurality of fuses configured to store a corresponding plurality of swap bits, wherein the plurality of swap bits are configured to be set to map the first column select signal to an address of the second column select signal; and
a controller coupled to the memory device, the controller configured to provide at least one command to set one or more of the plurality of swap bits.

11. The system of claim 10, wherein the memory array comprises a plurality of physical column planes including the physical column plane, wherein one or more of the plurality of physical column planes include less than sixty-four column select signals, wherein the plurality of physical column planes are configured to be arranged into a plurality of virtual planes each including sixty-four column select signals in a storage mode of a plurality of storage modes.

12. The system of claim 11, wherein the one or more of the plurality of swap bits set by the command are based, at least in part, on the column select signals included in the plurality of physical column planes.

13. The system of claim 10, wherein the one or more of plurality of swap bits are configured to flip a corresponding number of most significant bits of the address when set.

14. The system of claim 13, wherein the number of most significant bits is two.

15. A method, comprising:
receiving, at a memory device, a command indicating one or more of a plurality of swap bits to set;
responsive to the command, programming one or more of a plurality of fuses to set the one or more of the plurality of swap bits; and
responsive to programming the one or more of the plurality of fuses, remapping an address from a first column select of a column plane to a second column select of the column plane.

16. The method of claim 15, wherein the programming comprises setting two of the plurality of fuses to flip two bits of the address.

17. The method of claim 16, wherein the two bits comprise two most significant bits of the address.

18. The method of claim 15, further comprising broadcasting the plurality of swap bits from the plurality of fuses to a fuse register.

19. A method, comprising:
providing to a memory device, a command indicating one or more of a plurality of swap bits to set by programming one or more fuses of the memory device to cause the memory device to remap an address from a first column select of a column plane to a second column select of the column plane of a memory array of the memory device.

20. The method of claim 19, further comprising:
testing the memory device; and
responsive to the testing, determining the first column select is defective,
wherein the command is provided responsive to the determining.

21. The method of claim 19, further comprising packaging the memory device.

22. The method of claim 19, wherein the command is provided by a memory controller.

23. The method of claim 19, wherein the command is provided by a testing device.
